(19) United States
(12) Patent Application Publication
(10) Pub. No.: US 2023/0395461 A1
(43) Pub. Date: Dec. 7, 2023

(54) Semiconductor Device and Method Forming Same

(71) Applicant: Taiwan Semiconductor Manufacturing Co., Ltd., Hsinchu (TW)

(72) Inventors: Wen-Yi Lin, New Taipei City (TW); Kuang-Chun Lee, New Taipei City (TW); Chien-Chen Li, Hsinchu (TW); Chien-Li Kuo, Hsinchu (TW); Kuo-Chio Liu, Hsinchu (TW)

(21) Appl. No.: 17/833,208

(22) Filed: Jun. 6, 2022

(51) Int. Cl. H01L 23/427; H01L 25/065; H01L 21/48; H01L 23/498

(52) U.S. Cl. CPC H01L 23/4275; H01L 25/0655; H01L 21/4882; H01L 23/49833; H01L 2924/35121; H01L 2924/3511; H01L 2924/1611; H01L 2924/1616; H01L 2924/16235; H01L 2924/16251; H01L 2924/1632; H01L 2924/1659; H01L 2924/165; H01L 24/73

(57) ABSTRACT

Package structures and methods of forming package structures are discussed. A package structure, in accordance with some embodiments, includes a package component with one or more integrated circuits adhered to a package substrate, a hybrid thermal interface material utilizing a combination of polymer based material with high elongation values and metal based material with high thermal conductivity values. The polymer based thermal interface material placed on the edge of the package component contains the metal based thermal interface material in liquid form.

### BACKGROUND

Integrated circuit packages may have a plurality of package components such as device dies and package substrates bonded together to increase the functionality and integration level. Due to the differences between different materials of the plurality of package components, warpage may occur. With the increase in the size of the packages, warpage become more severe. Further, as integrated circuit packages develop, the power density requirements of these integrated circuit packages increases which means greater heat generation within the integrated circuit package. This incurs some new problems which should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-5 illustrate the cross-sectional views of intermediate stages in the formation of a high performance computing package component, in accordance with some embodiments.

FIGS. 6-13B illustrate the cross-sectional views of intermediate stages in the formation of a high performance computing package including formation of hybrid thermal interface material layers, in accordance with some embodiments.

FIGS. 14A-14F illustrate the cross-sectional views of a high performance-computing package with a solid thermal interface material forming multiple containment regions, in accordance with some embodiments.

FIG. 15A-15F illustrate the cross-sectional views of a high performance computing package depicting an alternate pattern for the containment regions defined by the solid thermal interface material, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package and the method of forming the same are provided as embodiments of the ideas presented herein. In accordance with some embodiments of the present disclosure, a plurality of first package components (which may include a plurality of device dies) is bonded to a substrate. A plurality of Thermal Interface Materials (TIMs) are disposed on the plurality of first package components. The materials of some of the plurality of TIMs may be different from the materials of other ones of the plurality of TIMs. With the using of a plurality of TIMs rather than a single large TIM, the stress in the TIM is released, and delamination may be reduced while maintaining high thermal dissipation. Embodiments discussed herein are to provide examples to enable making or using the subject matter of this disclosure. Although method embodiments may be discussed as being performed in a particular order, other method embodiments may be performed in any order.

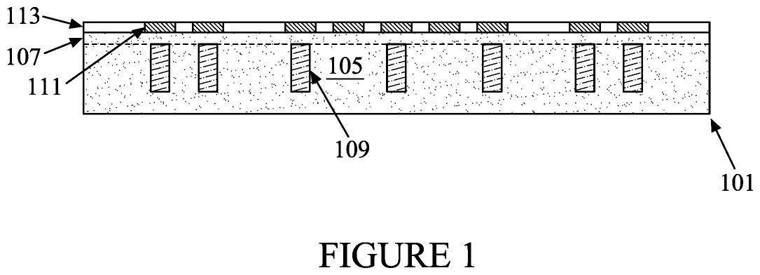

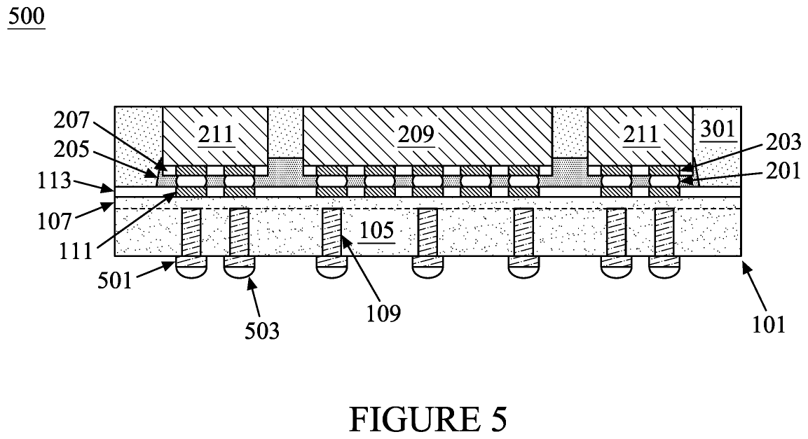

With reference now to FIGS. 1-5, these figures are cross-sectional views of a process for forming package components 500 (not illustrated in FIG. 1 but illustrated and discussed further below with respect to FIG. 5), such as package components for chip-on-wafer-on-substrate (CoWoS) devices. The package components 500 may be chip-on-wafer (CoW) package components.

In FIG. 1, a package component substrate 101 is obtained or formed. The package component substrate 101 comprises devices which will be singulated in subsequent processing to be included in the package component 500. The devices in the package component substrate 101 may be silicon interposers, organic interposers, integrated circuit dies, or the like. In some embodiments, the package component substrate 101 may include a package component wafer 105, an interconnect structure 107, conductive vias 109, first die connectors 111 and a first dielectric layer 113.

The package component wafer 105 may be a bulk semiconductor substrate, a semiconductor-on-insulator (SOI) substrate, a multi-layered semiconductor substrate, or the like. The package component wafer 105 may include a semiconductor material, such as silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The package component wafer 105 may be doped or undoped. In embodiments where interposers are formed in the package component substrate 101, the package component wafer 105 generally does not include active devices therein, although the interposers may include passive devices formed in and/or on a front surface (e.g., the surface facing upward in FIG. 1) of the package component wafer 105. In embodiments where integrated circuit devices are formed in the package component substrate 101, active devices such as transistors, capacitors, resistors, diodes, and the like, may be formed in and/or on the front surface of the package component wafer 105.

The conductive vias 109 extend into the interconnect structure 107 and/or the package component wafer 105. The conductive vias 109 are electrically connected to metallization layer(s) of the interconnect structure 107 (once the interconnect structure 107 has been subsequently formed). The conductive vias 109 are also sometimes referred to as through substrate vias (TSVs). As an example to form the conductive vias 109, recesses can be formed in the interconnect structure 107 (if already partially formed) and/or the package component wafer 105 by, for example, etching, milling, laser techniques, a combination thereof, and/or the like. A thin dielectric material may be formed in the recesses, such as by using an oxidation technique. A thin barrier layer may be conformally deposited in the openings, such as by CVD, atomic layer deposition (ALD), physical vapor deposition (PVD), thermal oxidation, a combination thereof, and/or the like. The barrier layer may be formed of an oxide, a nitride, a carbide, combinations thereof, or the like. A conductive material may be deposited over the barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer is removed from a surface of the interconnect structure 107 or the package component wafer 105 by, for example, a chemical-mechanical polish (CMP). Remaining portions of the barrier layer and conductive material form the conductive vias 109.

The interconnect structure 107 is formed over the front surface of the package component wafer 105, and is used to electrically connect the conductive vias 109 and devices (if any) of the package component wafer 105. The interconnect structure 107 may include one or more dielectric layer(s) and respective metallization layer(s) in the dielectric layer(s). Acceptable dielectric materials for the dielectric layers include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. The metallization layer(s) may include conductive vias and/or conductive lines to interconnect any devices together and/or to an external device. The metallization layer(s) may be formed of a conductive material, such as a metal, such as copper, cobalt, aluminum, gold, combinations thereof, or the like. The interconnect structure 107 may be formed by a damascene process, such as a single damascene process, a dual damascene process, plating processes, combinations of these, or the like.

In some embodiments, the first die connectors 111 and the first dielectric layer 113 are at the front-side of the package component substrate 101. Specifically, the package component substrate 101 may include the first die connectors 111 and the first dielectric layer 113. The first die connectors 111 may be formed by, for example, plating or the like. The first die connectors 111 may be formed of a conductive metal, such as copper or the like. The first dielectric layer 113 laterally encapsulates the first die connectors 111. The first dielectric layer 113 may be a polymer, such as polybenzoxazole (PBO), polyimide, benzocyclobutene (BCB), or the like. In other embodiments, the first dielectric layer 113 is formed of a nitride such as silicon nitride; an oxide such as silicon oxide, PhosphoSilicate Glass (PSG), BoroSilicate Glass (BSG), Boron-doped PhosphoSilicate Glass (BPSG), or the like; or the like. The first dielectric layer 113 may be formed by any acceptable deposition process, such as spin coating, chemical vapor deposition (CVD), laminating, the like, or a combination thereof.

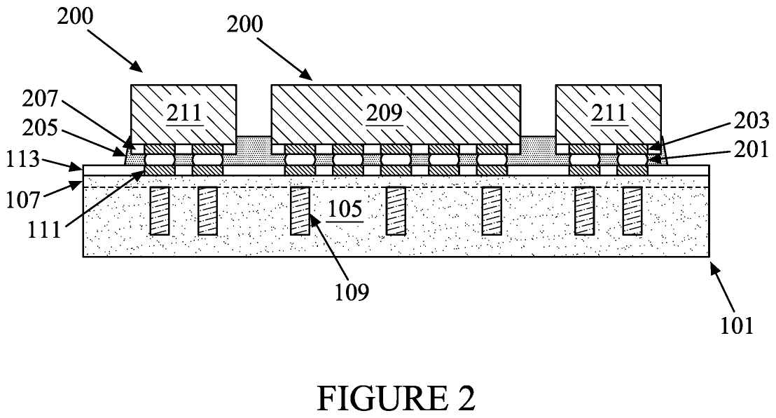

In FIG. 2, integrated circuit dies 200 (e.g., a first integrated circuit die 209 and a plurality of second integrated circuit dies 211) are attached to the package component substrate 101. In the embodiment shown, multiple integrated circuit dies 200 are placed adjacent one another, including the first integrated circuit dies 209 and the second integrated circuit dies 211, where the first integrated circuit die 209 is between the second integrated circuit dies 211. In some embodiments, the first integrated circuit die 209 is a logic device, such as a CPU, GPU, or the like, and the second integrated circuit dies 211 are memory devices, such as DRAM dies, HMC modules, high bandwidth memory modules, or the like. In some embodiments, the first integrated circuit die 209 is the same type of device (e.g., SoCs) as the second integrated circuit dies 211.

In the illustrated embodiment, the integrated circuit dies 200 are attached to the package component substrate 101 with first conductive connectors 201, such as solder bonds and the like. The integrated circuit dies 200 may be placed on the package component substrate 101 using, e.g., a pick-and-place tool. The first conductive connectors 201 may be formed of a conductive material that is reflowable, such as solder, copper, aluminum, gold, nickel, silver, palladium, tin, the like, or a combination thereof. In some embodiments, the first conductive connectors 201 are formed by initially forming a layer of solder through methods such as evaporation, electroplating, printing, solder transfer, ball placement, or the like. Once a layer of solder has been formed on the structure, a reflow may be performed in order to shape the first conductive connectors 201 into desired bump shapes. Attaching the integrated circuit dies 200 to the package component substrate 101 may include placing the integrated circuit dies 200 on the package component substrate 101 and reflowing the first conductive connectors 201. The first conductive connectors 201 form joints between the first die connectors 111 of the package component substrate 101 and second die connectors 203 the integrated circuit dies 200, electrically connecting the package component substrate 101 to the integrated circuit dies 200.

A package component underfill 205 may be formed around the first conductive connectors 201, and between the package component substrate 101 and the integrated circuit dies 200. The package component underfill 205 may reduce stress and protect the joints resulting from the reflowing of the first conductive connectors 201. The package component underfill 205 may be formed of an underfill material such as a molding compound, epoxy, or the like. The package component underfill 205 may be formed by a capillary flow process after the integrated circuit dies 200 are attached to the package component substrate 101, or may be formed by a suitable deposition method before the integrated circuit dies 200 are attached to the package component substrate 101. The package component underfill 205 may be applied in liquid or semi-liquid form and then subsequently cured.

In other embodiments (not separately illustrated), the integrated circuit dies 200 are attached to the package component substrate 101 with direct bonds. For example, hybrid bonding, fusion bonding, dielectric bonding, metal bonding, or the like may be used to directly bond second dielectric layers 207 and/or second die connectors 203 of the integrated circuit dies 200 to the first dielectric layers 113 and/or the first die connectors 111 of the package component substrate 101 without the use of adhesive or solder. The package component underfill 205 may be omitted when direct bonding is used. Further, a mix of bonding techniques could be used, e.g., some integrated circuit dies 200 could be attached to the package component substrate 101 by solder bonds, and other integrated circuit dies 200 could be attached to the package component substrate 101 by direct bonds.

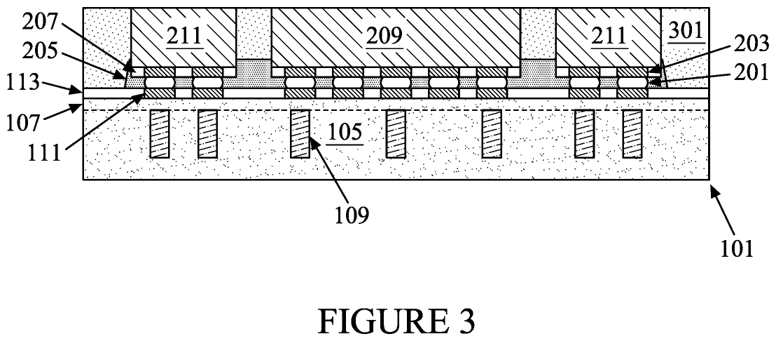

In FIG. 3, a package component encapsulant 301 is formed on and around the integrated circuit dies 200. After formation, the package component encapsulant 301 encapsulates the integrated circuit dies 200, and the package component underfill 205 (if present) or the first conductive connectors 201. The package component encapsulant 301 may be a molding compound, epoxy, or the like. The package component encapsulant 301 may be applied by compression molding, transfer molding, or the like, and is formed over the package component substrate 101 such that the integrated circuit dies 200 are buried or covered. The package component encapsulant 301 may be applied in liquid or semi-liquid form and then subsequently cured. The package component encapsulant 301 may be thinned to expose the integrated circuit dies 200. The thinning process may be a grinding process, a chemical-mechanical polish (CMP), an etch-back, combinations thereof, or the like. After the thinning process, the top surfaces of the integrated circuit dies 200 and the package component encapsulant 301 are coplanar (within process variations) such that they are level with one another. The thinning is performed until a desired amount of the integrated circuit dies 200 and/or the package component encapsulant 301 has been removed.

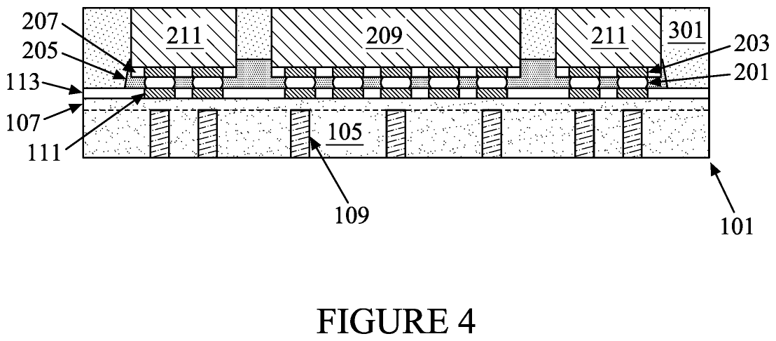

In FIG. 4, the package component wafer 105 is thinned to expose the conductive vias 109. Exposure of the conductive vias 109 may be accomplished by a thinning process, such as a grinding process, a chemical-mechanical polish (CMP), an etch-back, combinations thereof, or the like. In some embodiments (not separately illustrated), the thinning process for exposing the conductive vias 109 includes a CMP, and the conductive vias 109 protrude at the back-side of the package component substrate 101 as a result of dishing that occurs during the CMP. In such embodiments, an insulating layer (not separately illustrated) may optionally be formed on the back surface of the package component wafer 105, surrounding the protruding portions of the conductive vias 109. The insulating layer may be formed of a silicon-containing insulator, such as, silicon nitride, silicon oxide, silicon oxynitride, or the like, and may be formed by a suitable deposition method such as spin coating, CVD, plasma-enhanced CVD (PECVD), high density plasma CVD (HDP-CVD), or the like. After the package component wafer 105 is thinned, the exposed surfaces of the conductive vias 109 and the insulating layer (if present) or the package component wafer 105 are coplanar (within process variations) such that they are level with one another, and are exposed at the back-side of the package component substrate 101.

In FIG. 5, package component under-bump metallizations (UBMs) 501 are formed on the exposed surfaces of the conductive vias 109 and the package component wafer 105. As an example to form the package component UBMs 501 in this embodiment, a seed layer (not separately illustrated) is formed over the exposed surfaces of the conductive vias 109 and the package component wafer 105. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the package component UBMs 501. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the package component UBMs 501.

Further, second conductive connectors 503 are formed on the package component UBMs 501. The second conductive connectors 503 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The second conductive connectors 503 may include a conductive material such as solder, copper, aluminum, gold, nickel, silver, palladium, tin, the like, or a combination thereof. In some embodiments, the second conductive connectors 503 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the second conductive connectors 503 comprise metal pillars (such as copper pillars) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

Further, a singulation process is performed by cutting along scribe line regions (not shown) resulting in the package component 500. The singulation process may include sawing, dicing, or the like. For example, the singulation process can include sawing the package component encapsulant 301, the interconnect structure 107, and the package component wafer 105. The singulation process singulates an individual package component 500 from adjacent package components 500.

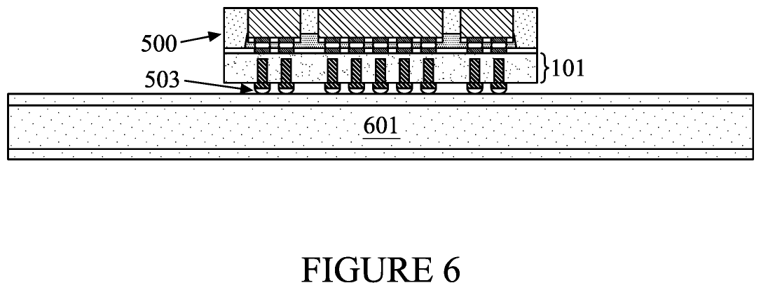

FIG. 6 illustrates a cross-sectional view of the package component 500 bonded on a substrate 601. The substrate 601 may be a printed circuit board (PCB) or the like. The substrate 601 may include one or more dielectric layers and electrically conductive features, such as conductive lines and vias. In some embodiments, the substrate 601 may include through-vias, active devices, passive devices, and the like. The substrate 601 may further include conductive pads formed at the upper and/or lower surfaces of the substrate 601. The second conductive connectors 503 may be coupled to conductive pads at the top surface of the substrate 601. The second conductive connectors 503 may be reflowed to bond the package component substrate 101 to the substrate 601. Other bonding schemes such as metal-to-metal direct bonding, hybrid bonding, or the like, may also be used for bonding package components 500 to the substrate 601.

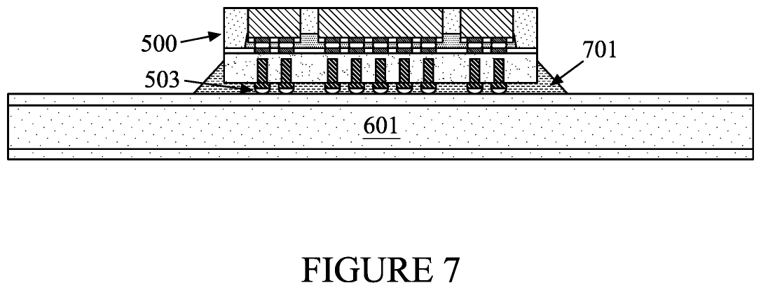

FIG. 7 illustrates after the package component 500 is bonded onto the substrate 601, a package underfill 701 may be dispensed in the gap between the package component 500 and the substrate 601. The package underfill 701 may reduce stress and protect the joints resulting from the reflowing of the second conductive connectors 503. The package underfill 701 may be formed of an underfill material such as a molding compound, epoxy, or the like. The package underfill 701 may be formed by a capillary flow process after the package component 500 is attached to the substrate 601, or may be formed by a suitable deposition method before package component 500 is attached to the substrate 601. The package underfill 701 may be applied in liquid or semi-liquid form and then subsequently cured.

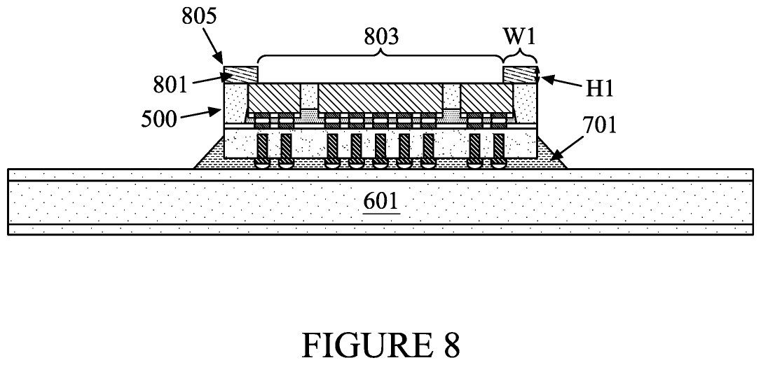

FIG. 8 illustrates a placement of a first thermal interface material (TIM) 801 attached to a top surface of the package component 500. While one of the first TIM 801 is illustrated, there may be one, two or more first TIMs 801 attached to the package component 500. The first TIM 801 may be a film-type TIM when placed, which is a pre-formed solid TIM at the time it is attached to the package component 500. The first TIM 801 may be rigid, and may be attached through picking and placing. In accordance with another embodiment the first TIM 801 may be a soft film, and may be rolled to the intended place, and is then pushed toward the package component 500. Any suitable method of dispensing the first TIM 801 may be utilized.

The first TIM 801 may be a phase-change material (PCM) that is solid at a temperature less than 40° C., such as at room temperature (e.g. 20° C.), and liquid at temperatures greater than 40° C. such as about 45° C. The first TIM 801 may have thermal conductivity values between about 5 W/mk and about 10 W/mk, such as about 8.5 W/mk. The thermal conductivity value may in part be related to an amount of a conductive filler present in the first TIM 801. In an embodiment, the greater a percent of the first TIM 801 that comprises the conductive filler the higher the thermal conductivity value of the first TIM 801 will be. The first TIM 801 may have an elongation percent greater than 30%, such as about 100%. The first TIM 801 may have a Young's modulus value of about 10 MPa or less at room temperature. The Young's modulus value may in part contribute to reducing a risk of delamination at corners of the package component 500. In an embodiment, the lower the Young's modulus value of the first TIM 801 the lower the risk of delamination at the corners of the package component 500 will be. The first TIM 801 may have a glass-transition temperature (Tg) or about 45° C. to about 60° C. The first TIM 801 may have a coefficient of thermal expansion (CTE) of about 40 ppm/° C. or greater. In an embodiment, a final state of the first TIM 801 may exist where the Young's Modulus, the CTE and the Tg of the final state of the first TIM 801 can be detected by a Nanoindentor and the thermal conductivity value of the final state of the first TIM 801 can be detected by a laser flash method. In a particular embodiment, the first TIM 801 may be a material such as commercially available Honeywell PCM, FujiPoly PCM, Laird PCM, combinations of these, or the like. In accordance with another embodiment the first TIM 801 may be formed of polymer material such as an epoxy resin.

Once placed, the first TIM 801 may be in contact with a top surface of the first integrated circuit dies 209, and may, or may not, be kept apart from a top surface of the second integrated circuit dies 211. The first TIM 801 may or may not extend over and contacting a top surface of the package component encapsulant 301. In an embodiment the first TIM 801 covers an edge portion of the top surface of the package component 500, leaving an interior portion of the top surface of the package exposed and forming a boundary region 803. The boundary region 803 has a boundary region height H1 the same as the first TIM 801, at the edge of the package component 500, such as between about 0.15 mm and about 0.25 mm, such as about 0.20 mm, and is outlined by a boundary region structure 805 with a boundary region structure width W1 between about 1 mm and about 5 mm, such as about 3 mm.

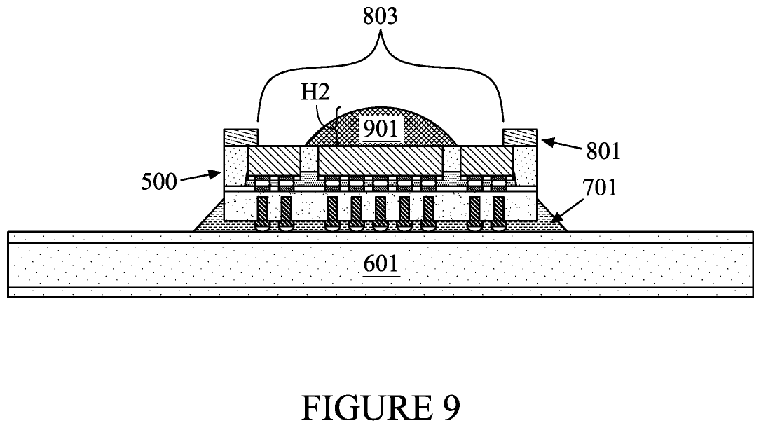

FIG. 9 illustrates dispensing of a second TIM 901 on to the interior portion of the top surface of the package component 500 within the boundary region 803 formed by the first TIM 801. In accordance with an embodiment the second TIM 901 is a liquid TIM and may be dispensed from a nozzle. When dispensed the second TIM 901 may cover only part of the interior portion of the top surface of the package component 500. In accordance with another embodiment when dispensed the second TIM 901 may cover the entirety of the interior portion of the top surface of the package component 500. When dispensed, the second TIM 901 has a peak height H2 marked by a thickest region of the second TIM 901. The peak height H2 may be equal to or greater than boundary region height H1.

The second TIM 901 may have thermal conductivity values between about 15 W/mk and about 90 W/mk, such as about 20 W/mk. The second TIM 901 may have a viscosity of less than 0.1 Pa*s. The second TIM 901 may be formed of a liquid metal TIM, such as gallium alloys. In accordance with an embodiment the liquid metal TIM may be 61Ga/25In/13In1Zn, 62.5Ga/21.5In/16Sn, 68Ga/20In/12Sn, 75.5Ga/24.5In, 95Ga/51n, 98Ga/2Ag and 100Ga.

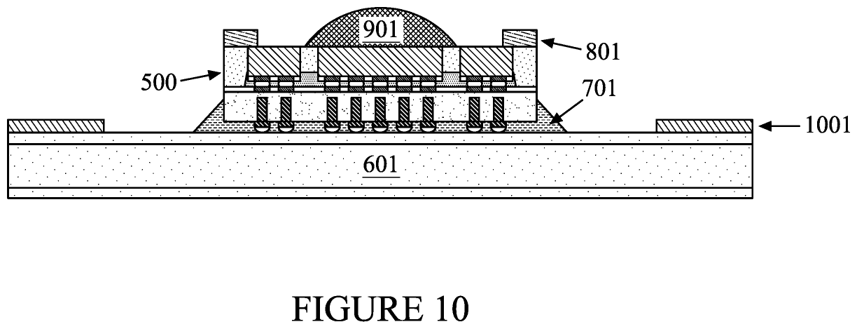

FIG. 10 illustrates the dispensing of adhesive 1001, which is dispensed onto a top surface of the substrate 601. The adhesive 1001 may be dispensed as a ring encircling package component 500, or may be dispensed as discrete portions aligning to a ring. The thermal conductivity value of the adhesive 1001 may be lower than the thermal conductivity of the first TIMs 801 and the second TIMs 901, respectively. For example, the thermal conductivity value of the adhesive 1001 may be lower than about 1 W/mk. In accordance with some embodiments, the dispensing of the adhesive 1001 is skipped.

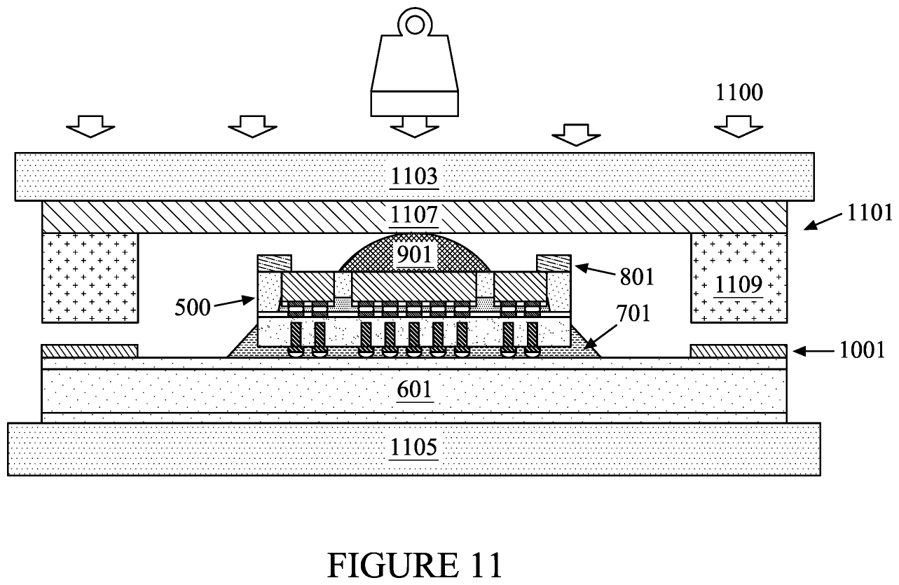

FIG. 11 illustrates an attachment process 1100 in which heat sink 1101 (which may also be metal lid) is attached to the first TIM 801 and the substrate 601 utilizing a first processing plate 1103 and a second processing plate 1105 to press the heat sink 1101 against the first TIM 801 at an elevated temperature.

In accordance with some embodiments the heat sink 1101 includes an upper portion 1107 and a lower portion 1109. The lower portion 1109 extends down from the upper portion 1107 of the heat sink 1101 to join the adhesive 1001. In accordance with an embodiment, the lower portion 1109 may form a full ring encircling the package component 500. In accordance with an embodiment, the heat sink 1101 does not include lower portion 1109. Accordingly, the process for dispensing the adhesives 1001 may be skipped. In accordance with some embodiments, heat dissipating fins (not shown) are attached to the heat sink 1101 through a fin TIM (not shown). In other embodiments, no heat sink fins are attached.

In an embodiment the heat sink 1101 may be fixed to the first processing plate 1103 and the substrate 601 may be fixed to the second processing plate 1105 during the attachment process 1100. The first processing plate 1103 is situated above the second TIM 901 so that a bottom surface of the upper portion 1107 (bottom surface of 1101 in embodiments where the lower portion 1109 is absent) is in contact with the second TIM 901 at the peak height H2. During the attachment process 1100 the heat sink 1101 is pushed against the adhesive 1001 and the first TIM 801 and the second TIM 901 with a force between about 3 kgf to about 20 kgf, such as about 10 kgf. Further, the attachment process 1100 is carried out at a temperature between about 70° C. and about 120° C., such as about 90° C. and is carried out for a duration of time ranging between about 20 min to about 60 min, such as about 30 min. However, any suitable parameters may be utilized.

During the attachment process 1100 the heat sink 1101 presses against the second TIM 901 causing the second TIM 901 to further spread out across the interior portion or the top surface of the package component 500 while remaining confined within the boundary region 803. Following the attachment process 1100 the bottom surface of the upper portion 1107 (bottom surface of 1101 in embodiments where the lower portion 1109 is absent) is planar with both the first TIM 801 and the second TIM 901. Further, the attachment process causes the second TIM 901 to spread across the top surface of the package component 500 to cover 50% or greater of the top surface of the package component 500.

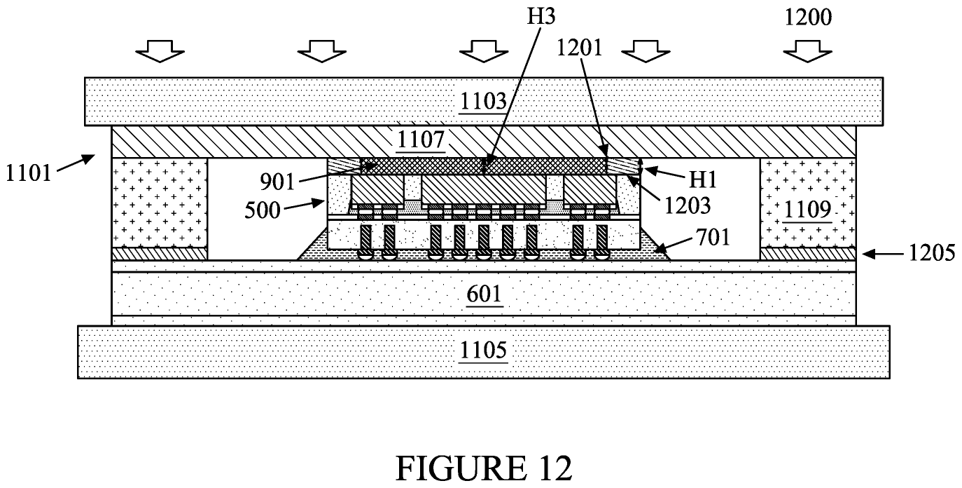

FIG. 12 illustrates a curing process 1200 in which the first TIM 801, the second TIM 901 and the adhesives 1001 are cured. The curing process 1200 may include a thermal curing process. The curing process 1200 may be performed at a temperature in a range between about 125° C. and about 180° C., such as about 150° C. The curing process 1200 may be performed for a duration in a range between about 30 minutes and about 180 minutes, such as about 105 minutes. During the curing process 1200 both the first TIM 801 and the second TIM 901 may exist in a liquid state. Further, a first interface 1201 exists between the first TIM 801 and the second TIM 901 following the attachment process 1100 and the first TIM 801 in a liquid state may intermingle with the second TIM 901 in a liquid state during the curing process 1200 at the first interface 1201.

FIG. 12 further illustrate that following the attachment process 1100 where the heat sink pressed against the second TIM 901 the second TIM 901 is spread across the top surface of the package component 500 within the boundary region 803. In accordance with an embodiment the curing process 1200 may cause cross-linking of the polymers within the first TIM 801 resulting in a first cross-linked gel 1203. The first cross-linked gel 1203 has greater toughness than the first TIM 801 prior to curing due to the presence of cross-linked polymers formed during the curing process 1200. Additionally, the curing process 1200 results in better adhesion between the first TIM 801 and the heat sink 1101 due to the hardening of the first TIM 801. Further, the intermingling of the first TIM 801 and the second TIM 901 at the first interface 1201 may also undergo cross-linking during the curing process 1200 resulting in a second cross-linked gel at the first interface 1201. In an embodiment utilizing the adhesive 1001 the curing process 1200 solidifies adhesive 1001 resulting in better adhesion between the adhesive 1001 and the heat sink 1101.

Following the curing process 1200 the second TIM 901 may have a cured height H3 at a center point on the top surface of the package component 500 of about 0.06 mm to about 0.10 mm, such as about 0.08 mm. Both the first TIM 801 and the second TIM 901 are in contact with both the heat sink 1101 and the top surface of the package component 500, the boundary region height H1 may be greater than the cured height H3. However, any suitable heights may be utilized.

Additionally, in some embodiments the package component 500 may become warped during the manufacturing processes so that the top surface of the package component 500 arcs upwards towards the heat sink 1101 from the perimeter of the top surface of the package component 500 towards the center of the top surface of the package component 500. As such, in some embodiments the warping of the package component 500 may result in the thickness of the second TIMs 901 being thinner towards the center of the top surface of the package component 500 than the thickness of the second TIMs 901 towards the perimeter of the top surface of the package component 500. Further, the thickness of the second TIMs 901 towards the center of the top surface of the package component 500 (e.g., the cured height H3) may be thinner than the boundary region height H1 at an edge of the first cross-linked gel 1203.

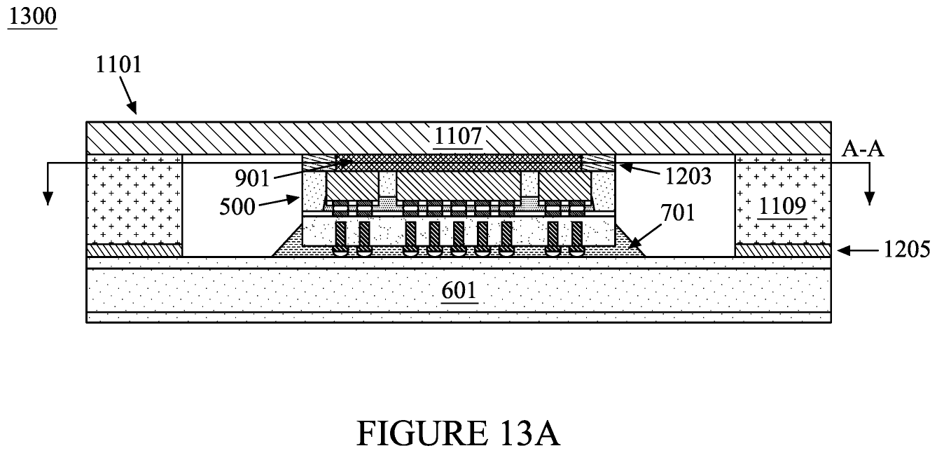

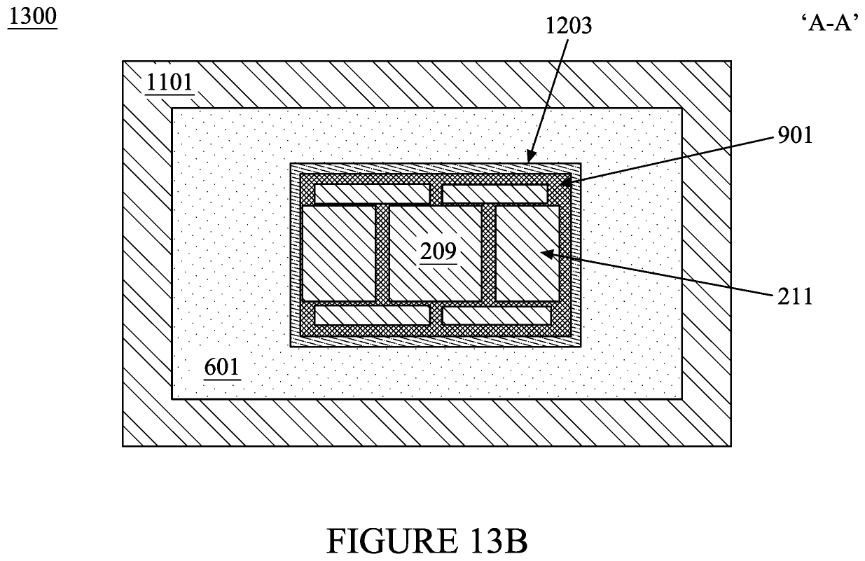

FIG. 13A-13B depict different cross section views of a semiconductor device package 1300 following the attachment process 1100 and the curing process 1200. In accordance with an embodiment the semiconductor device package 1300 may be a High Performance Computing (HPC) package. FIG. 13A illustrates the removal of the first processing plate 1103 and the second processing plate 1105 following completion of the curing process 1200. FIG. 13A additionally illustrates a section cut A-A. FIG. 13B illustrates a cross-section top-down view ‘A-A’ taken from the section cut A-A depicting the boundary region 803 filled in by the second TIM 901 within the first cross-linked gel 1203. In FIG. 13B the first TIM 801 and the second TIM 901 are depicted as semi-transparent to illustrate a coverage of the first TIM 801 and the second TIM 901 over the first integrated circuit dies 209 and the second integrated circuit dies 211 of the package component 500. Further, FIG. 13B depicts other potential devices that may be present in the package component 500 such as interposers, integrated circuits, and the like.

By utilizing the first TIM 801 and the second TIM 901 as discussed in the embodiments presented above advantages can be achieved. The use of metal for the second TIM 901 sees the benefits of high thermal conductivity values for metal. Further, the use of liquid metal for the second TIM 901 sees the benefit of not needing to perform a pre-process such as a backside metallization process. The use of a phase-change material for the first TIM 801 allows for the containment of the metal liquid while seeing the benefit of high elongation values to help with delamination and crack risks during temperature cycle tests. The curing process 1200 improves the durability of the first TIM 801 by forming the first cross-linked gel 1203 and the cross-linked products at the first interface 1201 results in better transition between the first TIM 801 and the second TIM 901.

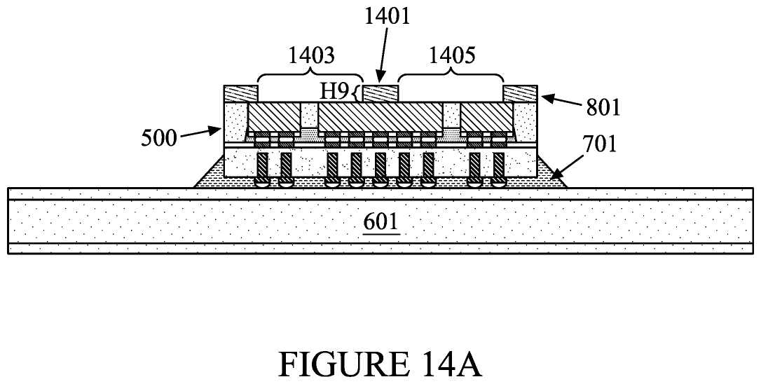

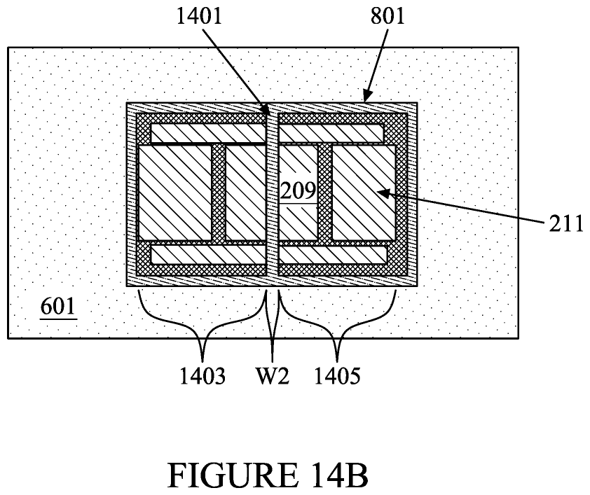

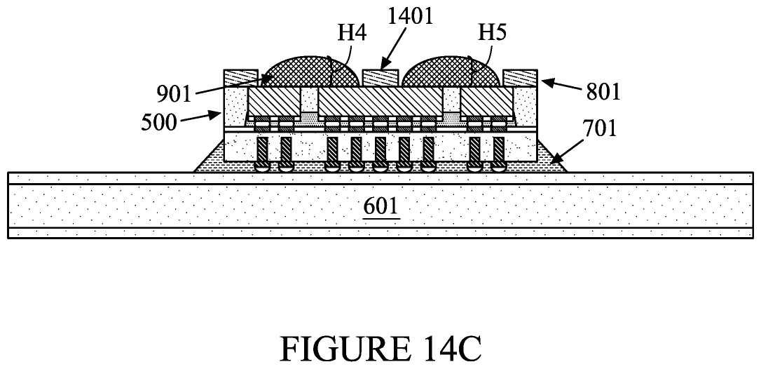

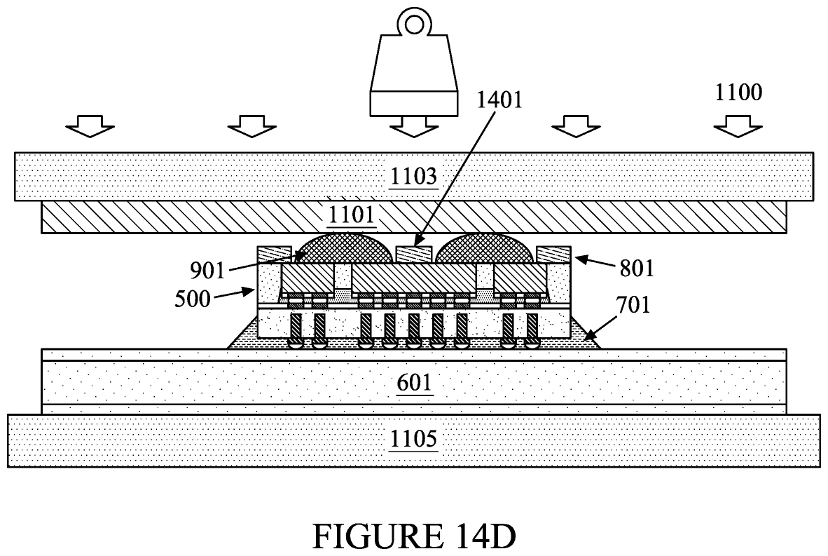

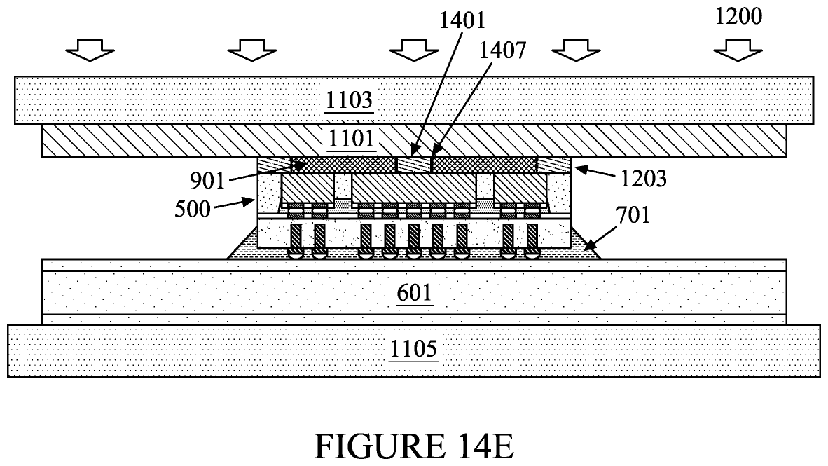

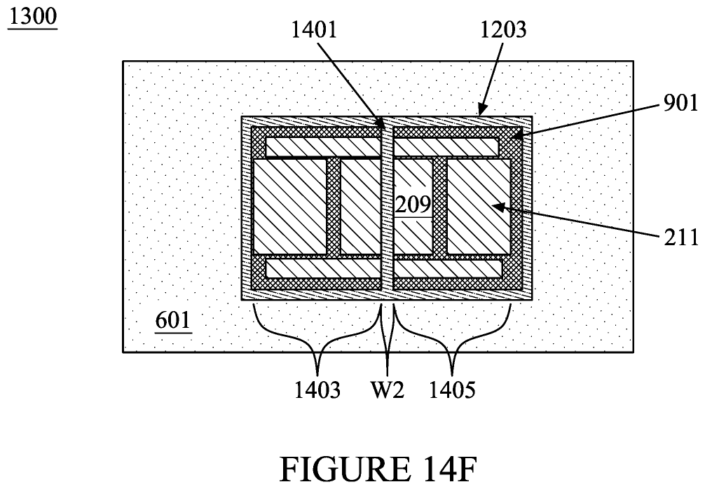

FIGS. 14A-14F illustrate another embodiment in which the first TIMs 801, in addition to being placed on the perimeter of the top surface of the package component 500, is additionally placed in a first strip 1401 across the interior portion. The result is at least two isolated regions within the boundary region 803 on the top surface of the package component 500.

FIG. 14A depicts the resulting structure as formed from similar steps as previously discussed with respect to FIGS. 1-7 and further the placement of the first TIMs 801 on the perimeter of the top surface of the package component 500 as well as the placement of the first strip 1401 of the first TIMs 801 in the interior of the top surface of the package component 500. In accordance with an embodiment the placement of the first strip 1401 of the first TIMs 801 in the interior of the top surface of the package component 500 may be across the middle of the top surface of the package component 500 or may be offset from the middle of the top surface of the package component 500. The first strip 1401 has a first strip height H9, the first strip height H9 ranging between about 0.08 mm and about 0.2 mm, such as 0.15 mm. The boundary region 803 (as depicted in FIG. 8) in this embodiment comprises at least two isolated regions, such as a first isolated region 1403 and a second isolated region 1405. The size of the first isolated region 1403 may be less than, greater than, or equal to the size of the second isolated region 1405, depending on the placement of the first strip 1401.

FIG. 14B depicts a top down view in which the area of the first isolated region 1403 separated by the first strip 1401 from the second isolated region 1405 can be seen. The first strip 1401 may have a second width W2 between about 1 mm and about 5 mm, such as about 3 mm and may be equal to the first width W1.

FIG. 14C depicts the dispensing of the second TIMs 901 into both the first isolated region 1403 and the second isolated region 1405. The amount of the second TIM 901 dispensed into the first isolated region 1403 and the second isolated region 1405 is dependent on the size of the first isolated region 1403 and the second isolated region 1405, respectively. Accordingly, if the size of the first isolated region 1403 is greater than the size of the second isolated region 1405, more of the second TIMs 901 will be dispensed into the first isolated region 1403. A first isolated region peak height H4 exists at the thickest region of the dispensed second TIM 901 in the first isolated region 1403. The first isolated region peak height H4 range from about 0.1 mm to about mm, such as about 0.2 mm. A second isolated region peak height H5 exists at the thickest region of the dispensed second TIM 901 in the second isolated region 1405. The second isolated region peak height H5 may range from about 0.1 mm to about 0.8 mm, such as about 0.2 mm. In an embodiment, the first isolated region peak height H4 is related to the chemical composition of the second TIM 901. Where the second TIM 901 is a liquid metal, the first isolated region peak height H4 is affected by the wettability of the liquid metal to the top surface of the package component 500, with the better the wettability of the liquid metal the smaller the first isolated region peak height H4 will be in part because the liquid metal is capable of covering a larger area in the first isolated region 1403 before the attachment process 1100. The first isolated region peak height H4 may be less than, greater than or equal to the second isolated region peak height H5. The first isolated region peak height H4 may be equal to or greater than the boundary region height H1. The second isolated region peak height H5 may be equal to or greater than the boundary region height H1.

FIG. 14D depicts the attachment process 1100 as previously discussed with respect to FIG. 11. In accordance with an embodiment with the first strip 1401 the heat sink 1101 has a bottom surface that is planar and contacting the second TIM 901 at a point corresponding to the greater of either the first isolated region peak height H4 or the second isolated region peak height H5. The bottom surface being planar with both the second TIMs 901 and the first TIMs 801 following the attachment process 1100. FIG. 14D further depicts an embodiment where the addition of the adhesive 1001 is skipped and the heat sink 1101 does not comprise the lower portion 1109.

FIG. 14E depicts the curing process 1200 as previously discussed with respect to FIG. 12. In accordance with an embodiment with the first strip 1401 a second interface 1407 between the first TIMs 801 and the second TIMs 901 exists between the first strip 1401 of the first TIM 801 and the second TIMs of both the first isolated region 1403 and the second isolated region 1405. During the curing process 1200 cross-linking will occur between the first TIMs 801 and the second TIMs 901 at both the first interface 1201 and the second interface 1407. The existence of the second interface 1407 may result in a greater amount of cross-linking between the first TIMs 801 and the second TIMs 901.

FIG. 14F depicts a top-down cross section view of the semiconductor device package 1300 in an embodiment with the first strip 1401 showing the first isolated region 1403 and the second isolated region 1405 filled in by the second TIM 901. The second TIM 901 is depicted as transparent to show the silhouette of devices such as first integrated circuit die 209 and second integrated circuits 211 underneath the second TIM 901.

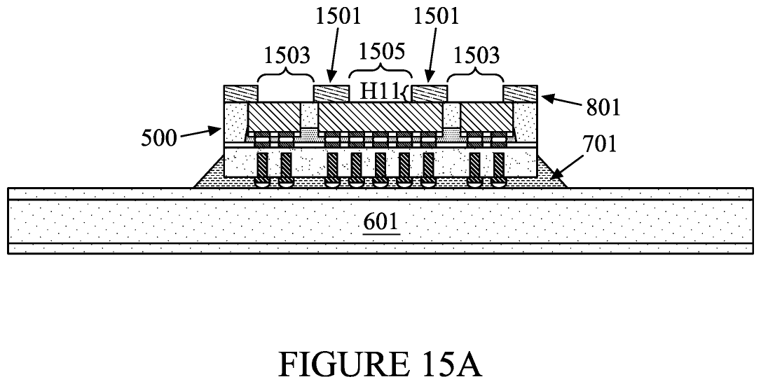

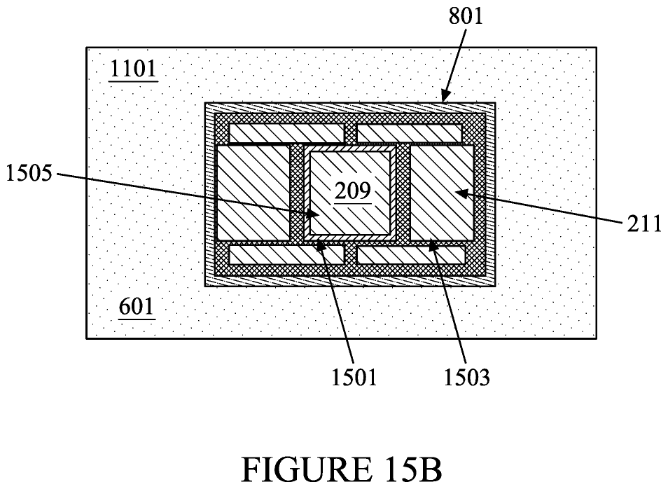

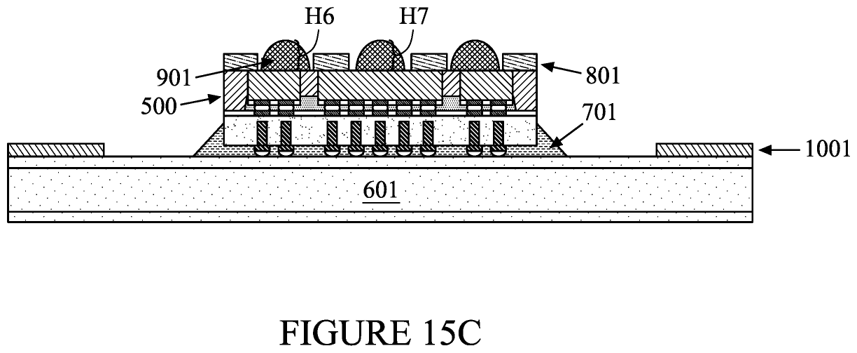

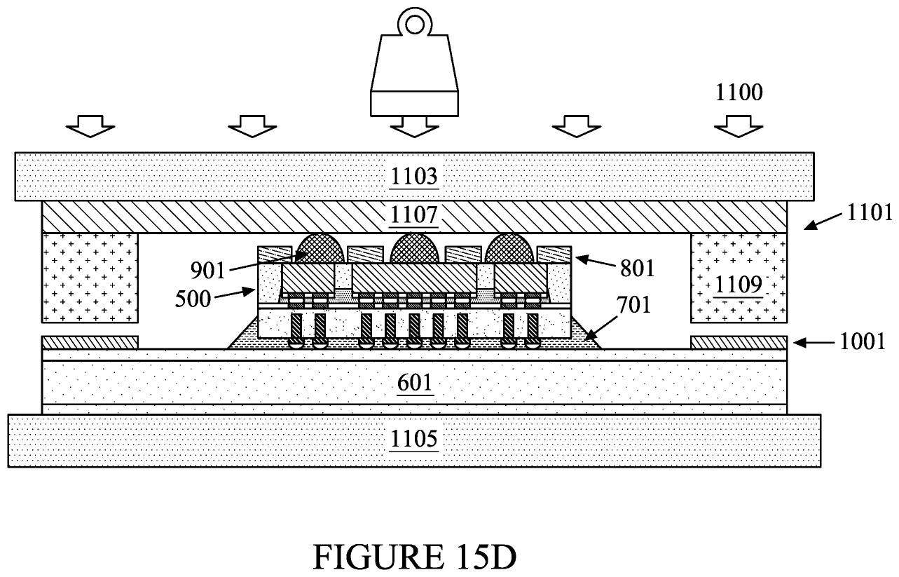

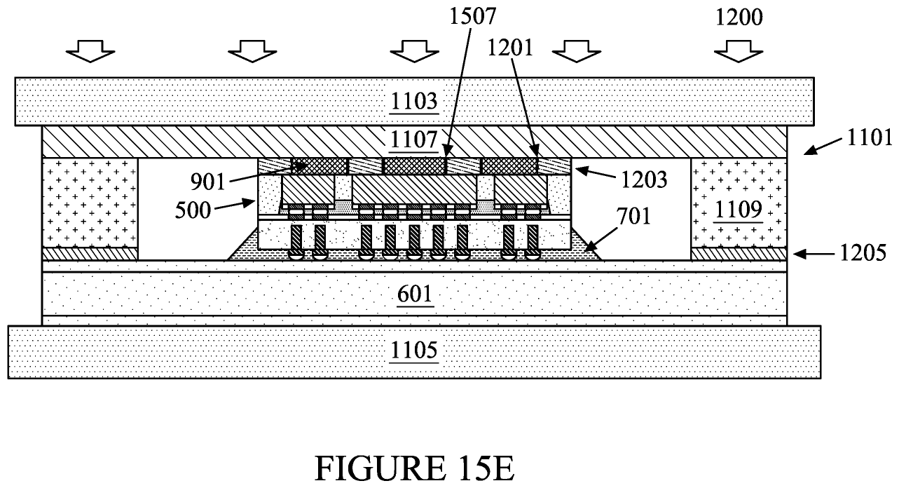

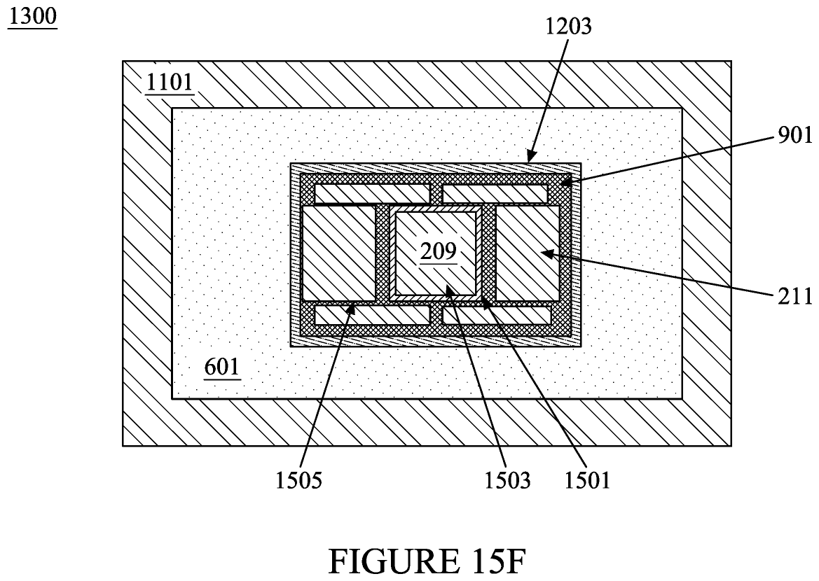

FIGS. 15A-15F illustrate an embodiment in which the first TIMs 801 in addition to being placed on the perimeter of the top surface of the package component 500 the first TIMs 801 is additionally placed on a perimeter of the top surface of the first integrated circuit dies 209 in the package component 500 forming a device boundary structure 1501 with a third isolated region 1503 outside the device boundary structure 1501 and a fourth isolated region 1505 inside the device boundary structure 1501.

FIG. 15A depicts the resulting structure as formed from similar steps as previously discussed with respect to FIGS. 1-7 and further the placement of the first TIMs 801 on the perimeter of the top surface of the package component 500 as well as the placement the first TIMs 801 along the perimeter of the top surface of the first integrated circuit dies 209 on the top surface of the package component 500 forming the device boundary structure 1501. The boundary device structure has a boundary device structure height H11, the boundary device structure H11 ranging between about 0.08 mm to about 0.2 mm, such as about 0.15 mm. the boundary region height H11. The boundary region 803 (as depicted in FIG. 8) is split into the third isolated region 1503 and the fourth isolated region 1505. The size of the third isolated region 1503 may be less than, greater than, or equal to the size of the fourth isolated region 1505, depending on the placement of the first TIM 801 along the perimeter of the top surface of the first integrated circuit dies 209.

FIG. 15B depicts a top down view in which the area of the third isolated region 1503 separated by the device boundary structure 1501 from the fourth isolated region 1505 can be seen. In an embodiment the third isolated region 1503 outside the perimeter of the device boundary structure 1501 encompasses the fourth isolated region 1505.

FIG. 15C depicts the dispensing of the second TIMs 901 into both the third isolated region 1503 and the fourth isolated region 1505. The amount of the second TIM 901 dispensed into the third isolated region 1503 and the fourth isolated region 1505 is dependent on the size of the third isolated region 1503 and the fourth isolated region 1505, respectively. Accordingly, if the size of the third isolated region 1503 is greater than the size of the fourth isolated region 1505, more of the second TIMs 901 will be dispensed into the third isolated region 1503 than the fourth isolated region 1505. Further, as depicted in FIG. 15B, the second TIMs 901 may be dispensed into multiple locations within either the third isolated region 1503 or the fourth isolated region 1505. A split isolated region peak height H6 exists at the thickest region of the dispensed second TIM 901 in the third isolated region 1503. The split isolated region peak height H6 may range from about 0.08 mm to about 0.15 mm, such as about 0.09 mm. A fourth isolated region peak height H7 exists at the thickest region of the dispensed second TIM 901 in the fourth isolated region 1505. The split isolated region peak height H6 may be less than, greater than or equal to the fourth isolated region peak height H7. The split isolated region peak height H6 may be equal to or greater than the boundary region height H1. The fourth isolated region peak height H7 may be equal to or greater than the boundary region height H1.

FIG. 15D depicts the attachment process 1100 as previously discussed with respect to FIG. 11. In accordance with an embodiment with the device boundary structure 1501 the bottom surface of the upper portion 1107 of the heat sink 1101 is planar and contacting the second TIM 901 at a point corresponding to the greater of either the split isolated region peak height H6 or the fourth isolated region peak height H7. The bottom surface of the upper portion 1107 of the heat sink 1101 being planar with both the second TIMs 901 and the first TIMs 801 following the attachment process 1100.

FIG. 15E depicts the curing process 1200 as previously discussed with respect to FIG. 12. In accordance with an embodiment with the device boundary structure 1501 a third interface 1507 between the first TIMs 801 and the second TIMs 901 exists between the first TIM 801 along the perimeter of the top surface of the first integrated circuit dies 209 and the second TIMs 901 of both the third isolated region 1503 and the fourth isolated region 1505. During the curing process 1200 cross-linking will occur between the first TIMs 801 and the second TIMs 901 at both the first interface 1201 and the third interface 1507. The existence of the third interface 1507 may result in a greater amount of cross-linking between the first TIMs 801 and the second TIMs 901.

FIG. 15F depicts a top-down cross section view of the semiconductor device package 1300 in an embodiment with the device boundary structure 1501. FIG. 15F shows the second TIM 901 filling both the third isolated region 1503 and the fourth isolated region 1505. The second TIM 901 is shown as partially transparent to show the silhouette of devices such as first integrated circuit die 209 and second integrated circuits 211 underneath the second TIM 901.

By adding additional first TIM 801 in the form of the first strip 1401 or the device boundary structure 1501 as discussed in the embodiments presented above advantages can be achieved. By utilizing the first TIM 801 having a high elongation percentages in conjunction with the second TIM 901 having a high thermal conductivity value the issue of delamination at the corners of the package component 500 and the issue of heat dissipation throughout the semiconductor device package 1300 are both addressed. The high thermal conductivity values of the second TIM 901 is able to address potential high power density of about 70 W/cm\hat{ }2 to about 100 W/cm\hat{ }2, such as about 85 W/cm\hat{ }2, of the high performance computing package. The high elongation percentages of the first TIM 801 is able to address delamination and warpage stress along the corners of the package component 500. Additionally, the utilization of the first TIM 801 on the perimeter of the top surface of the package component 500 and the second TIM 901 on the interior area of the top surface of the package component 500 can see a normalized thermal resistance of 0.87 indicating better thermal dissipation and allowing for greater power density package components.

In accordance with some embodiments of the present disclosure a method of manufacturing a semiconductor device includes adhering a first Thermal Interface Material (TIM) over a first portion of a first package, wherein the first TIM is formed from a phase-change material, dispensing a second TIM over a second portion of the first package, wherein the second TIM is formed from a liquid metal, and attaching a heat sink to the first TIM. In an embodiment the first TIM covers an exterior area of the first package and the second TIM covers an interior area of the first package. In an embodiment further includes a first strip of the first TIM that bisects the first package, wherein the second portion further includes a first isolated region and a second isolated region. In an embodiment the first TIM covers a perimeter of a die in the first package and the second TIM covers a first isolated area outside the first TIM and a second isolated area inside the first TIM. In an embodiment the attaching the heat sink to the first TIM spreads the liquid metal across the second portion of the first package. In an embodiment further includes cross-linking the first TIM to form a cross-linked gel. In an embodiment further includes cross-linking the first TIM with the second TIM to form cross-linked product at an interface between the first TIM and the second TIM.

In accordance with some embodiments of the present disclosure a semiconductor device includes a boundary structure over a first top surface of a first semiconductor package, wherein the boundary structure is formed from a phase-change material, a metal thermal interface material (TIM) layer surrounded by the boundary structure, and a lid in physical contact with the boundary structure and the metal TIM layer. In an embodiment further includes a cross linked gel at an interface between the boundary structure and the metal TIM layer. In an embodiment the metal TIM layer includes a gallium alloy. In an embodiment the phase-change material has a thermal conductivity value of about 5 W/mk or greater and a Young's modulus value of about 10 MPa or less. In an embodiment the metal TIM layer is split into two or more isolated regions. In an embodiment the boundary structure has a first height and the metal TIM layer has a second height, the first height being greater than the second height. In an embodiment the boundary structure has a second top surface and the metal TIM layer has a third top surface, the second top surface being planar with the third top surface.

In accordance with some embodiments of the present disclosure a method of manufacturing a semiconductor device includes bonding a package component to a package substrate, forming a boundary layer on a perimeter of a first top surface of the package component, wherein the boundary layer includes a phase-change material, dispensing a liquid metal onto the package component within the perimeter, placing a heat sink in contact with the liquid metal, performing a clamping process, the clamping process includes pressing the heat sink towards the package substrate, and curing the boundary layer, wherein after the curing the boundary layer is solidified. In an embodiment the boundary layer has a glass-transition temperature between about 45° C. and about 60° C. In an embodiment the performing the clamping process spreads the liquid metal, the boundary layer keeping the liquid metal within the perimeter. In an embodiment after the clamping process the liquid metal has a second top surface that is planar with a bottom surface of the heat sink. In an embodiment the phase-change material has a melting point above 40° C. In an embodiment the pressing the heat sink towards the package substrate utilizes a first force between about 3 kgf and about 20 kgf and the clamping process is run at a temperature ranging between about 70° C. and about 120° C. for a period of time ranging between about 20 min and about 120 min.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device comprising:
adhering a first Thermal Interface Material (TIM) over a first portion of a first package, wherein the first TIM is formed from a phase-change material;
dispensing a second TIM over a second portion of the first package, wherein the second TIM is formed from a liquid metal; and
attaching a heat sink to the first TIM.

2. The method of claim 1, wherein the first TIM covers an exterior area of the first package and the second TIM covers an interior area of the first package.

3. The method of claim 2, further comprising a first strip of the first TIM that bisects the first package, wherein the second portion further comprises a first isolated region and a second isolated region.

4. The method of claim 1, wherein the first TIM covers a perimeter of a die in the first package and the second TIM covers a first isolated area outside the first TIM and a second isolated area inside the first TIM.

5. The method of claim 1, wherein the attaching the heat sink to the first TIM spreads the liquid metal across the second portion of the first package.

6. The method of claim 1, further comprising cross-linking the first TIM to form a cross-linked gel.

7. The method of claim 1, further comprising cross-linking the first TIM with the second TIM to form cross-linked product at an interface between the first TIM and the second TIM.

8. A semiconductor device comprising:
a boundary structure over a first top surface of a first semiconductor package, wherein the boundary structure is formed from a phase-change material;
a metal thermal interface material (TIM) layer surrounded by the boundary structure; and
a lid in physical contact with the boundary structure and the metal TIM layer.

9. The semiconductor device of claim 8, further comprising a cross linked gel at an interface between the boundary structure and the metal TIM layer.

10. The semiconductor device of claim 8, wherein the metal TIM layer comprises a gallium alloy.

11. The semiconductor device of claim 8, wherein the phase-change material has a thermal conductivity value of about 5 W/mk or greater and a Young's modulus value of about 10 MPa or less.

12. The semiconductor device of claim 8, wherein the metal TIM layer is split into two or more isolated regions.

13. The semiconductor device of claim 8, wherein the boundary structure has a first height and the metal TIM layer has a second height, the first height being greater than the second height.

14. The semiconductor device of claim 13, wherein the boundary structure has a second top surface and the metal TIM layer has a third top surface, the second top surface being planar with the third top surface.

15. A method of manufacturing a semiconductor device comprising:
bonding a package component to a package substrate;
forming a boundary layer on a perimeter of a first top surface of the package component, wherein the boundary layer comprises a phase-change material;
dispensing a liquid metal onto the package component within the perimeter;
placing a heat sink in contact with the liquid metal;
performing a clamping process, the clamping process comprising pressing the heat sink towards the package substrate; and
curing the boundary layer, wherein after the curing the boundary layer is solidified.

16. The method of claim 15, wherein the boundary layer has a glass-transition temperature between about 45° C. and about 60° C.

17. The method of claim 15, wherein the performing the clamping process spreads the liquid metal, the boundary layer keeping the liquid metal within the perimeter.

18. The method of claim 15, wherein after the clamping process the liquid metal has a second top surface that is planar with a bottom surface of the heat sink.

19. The method of claim 15, wherein the phase-change material has a melting point above 40° C.

20. The method of claim 15, wherein the pressing the heat sink towards the package substrate utilizes a first force between about 3 kgf and about 20 kgf and the clamping process is run at a temperature ranging between about 70° C. and about 120° C. for a period of time ranging between about 20 min and about 120 min.
